(19) United States
(12) Patent Application Publication
(10) Pub. No.: US 2005/0287483 A1
(43) Pub. Date: Dec. 29, 2005

(54) CONTACT HOLE PRINTING METHOD AND APPARATUS WITH SINGLE MASK, MULTIPLE EXPOSURES, AND OPTIMIZED PUPIL FILTERING

(75) Inventors: Michael Lercel, Fishkill, NY (US); Alan E. Rosenbluth, Yorktown Heights, NY (US); Nakgeuon Seong, Wappingers Falls, NY (US)

Correspondence Address: HOFFMAN WARNICK & D'ALESSANDRO, LLC, 75 STATE STREET, 14TH FL, ALBANY, NY, 12207, US

(73) Assignee: INTERNATIONAL BUSINESS MACHINES CORPORATION, Armonk, NY (US)

(21) Appl. No.: 10/710,168

(22) Filed: Jun. 23, 2004

(51) Int. Cl. G03F 7/20; G03C 5/00

(52) U.S. Cl. 430/394; 355/18

(57) ABSTRACT

The present invention provides a lithographic method and apparatus (e.g., for printing contact holes on a wafer) that use a single mask, multiple exposures, and optimized pupil filtering. The method comprises: providing a mask including pattern features to be transferred to a wafer; transferring a first set of pattern features from the mask to the wafer using a first type of illumination and a first type of pupil filter; and transferring a second set of pattern features from the mask to the wafer using a second type of illumination and a second type of pupil filter.

### BACKGROUND OF INVENTION

The present invention relates generally to manufacturing processes that require lithography and, in particular, to a contact hole printing method and apparatus that use a single mask, multiple exposures, and optimized pupil filtering.

There are several lithographic techniques that are aimed at addressing the error sensitivity of contact hole patterns. One such technique requires the exposure of multiple masks. For example, a circuit pattern is divided into two separate masks, and the numerical aperture (NA) and illumination are optimized for each of these masks during each of two exposures. This prior art method is problematic in that it requires that two masks be fabricated for each overall circuit pattern. This increases the cost of the lithographic process.

The double exposure/double mask technique described above is probably the best performing method known in the art to extend minimum printable pitch and/or improve critical dimension (CD) control. When two masks and two exposures are used, individual mask and exposure settings of an imaging tool can be optimized to maximize contrast and depth-of-field (DOF) for each exposure. Then, the next mask and exposure follows, resulting in a final pattern, which combines the two exposures. However, the current double exposure/double mask technique is founded on the presumed feasibility of exposing two masks. Its basic premise is that print fidelity can be improved by apportioning the circuit patterns between two masks (for example, on the basis of orientation, or pitch, or odd-vs.-even placement in a dense array), thereby allowing the individual exposures to be optimized differently for each group, and also providing a sometimes beneficial reduction in pattern density on each mask. Unfortunately, when two masks are used, the mask cost is doubled and throughput of the exposure tool is reduced to approximately half that of a single exposure process. Both of these factors result in severe increases of the cost of processing.

Another prior art technique used to address the error-sensitivity of contact hole lithography is the use of pupil filters together with illumination on-axis, or more precisely with a compact illumination source of small extent (usually disk-shaped) that is centered on axis. In its simplest form, this filter consists of a central obscuration, so that the unblocked rays which form the image all arrive from the outer portion of the pupil, and have approximately the same obliquity against the optical axis. In other words, the image rays are all tilted against the axis by about the same magnitude, though from different directions. This common phase runout against the axis increases depth of focus, but causes increased image background at large distances from the geometrical image point. As a result, the traditional pupil filter works well for printing isolated contacts, but performs poorly with dense contacts (small to moderate pitches). In order to achieve a limited ability to print less isolated contacts, this prior art technique resorts to custom-shaped transparent or transmission-controlled phase plates in the pupil plane, where the phase must be accurately and uniformly controlled. Even with such filters, this prior art pupil-filtering method does not provide coverage of as wide a pitch range as is desired in many applications.

Another prior art method to print contacts over a relatively wide pitch range is to surround the mask openings for isolated and semi-isolated contacts with sub-resolution assist features (SRAFs), which may be phase-shifted. These assist features reduce pupil intensity in orders that increase error sensitivity, but they cannot fully block out those orders, since the assist features must be held well below the printing resolution of the lithographic process. As such, sub-resolution assist features are very sensitive to mask fabrication error.

In view of the foregoing, there is a need for contact hole printing methods that obviate the deficiencies of the prior art.

### SUMMARY OF INVENTION

The present invention provides a lithographic process and apparatus (e.g., for printing contact holes on a wafer) that use a single mask, multiple exposures, and optimized pupil filtering. In particular, a multiple (e.g., double) exposure technique with single mask is used with optimized source and pupil filtering to improve depth-of-focus (DOF) with minimum throughput impact and no extra mask cost.

The present invention can be performed using a simple opaque circular filter plate, allowing relatively easy implementation in existing lithography tools. The present invention provides reduced error sensitivity over a wider pitch range than conventional pupil-filter methods. Source and pupil filtering are optimized for various pitches (e.g., by simulation), then split into two or more exposures to maximize DOF. The present invention improves the common process window (with particular enhancement of DOF) for a wide range of features when a single mask is exposed.

The present invention provides a contact hole patterning method and apparatus which use multiple exposures of a single mask to robustly print circuit patterns that contain many different pitches. Each exposure is individually optimized in numerical aperture (NA), illuminator (i.e. source pattern) and pupil filter to achieve in the combined exposure an enhanced common process window for all features.

Each exposure is targeted to enhance the printing capability of a particular group of features (for example, a particular range of pitches). This is achieved by choosing the NA, illuminator, and pupil filter for each exposure so as to resolve the targeted group of features while reducing transmission of diffracted light that increases error sensitivity in those printed patterns, i.e., by blocking part or all of the diffraction orders which increase error sensitivity in the primary image. Each such exposure thus robustly prints a particular group of features, and in the combined exposure all mask patterns are printed with low error sensitivity. In a preferred embodiment, two particular error sensitivities are emphasized during optimization of the optical parameters, namely sensitivity to defocus and sensitivity to mask error.

Unfiltered light from mask patterns which are outside the group that is targeted by a particular exposure will not seriously degrade depth of focus or mask tolerances, but will reduce exposure latitude somewhat. This is usually the preferred tradeoff since depth of focus and mask-error sensitivity are more serious problems when printing contact holes than is dose latitude.

A first aspect of the invention is directed to a method for printing a pattern on a wafer, comprising: providing a mask including pattern features to be transferred to a wafer; transferring a first set of pattern features from the mask to the wafer using a first type of illumination and a first type of pupil filter; and transferring a second set of pattern features from the mask to the wafer using a second type of illumination and a second type of pupil filter.

A second aspect of the invention is directed to an apparatus for printing a pattern on a wafer, comprising: a mask including pattern features to be transferred to a wafer; an illumination system for providing a first type of illumination for transferring a first set of pattern features from the mask to the wafer, wherein the first type of illumination is directed through a first type of pupil filter; and wherein the illumination system provides a second type of illumination for transferring a second set of pattern features from the mask to the wafer, through a second type of pupil filter.

A third aspect of the invention is directed to a method for printing a pattern on a wafer, comprising: providing a mask including pattern features to be transferred to a wafer; and transferring a plurality of sets of pattern features from the mask to the wafer using a single exposure and multiple polarization channels.

The foregoing and other features of the invention will be apparent from the following more particular description of embodiments of the invention.

### BRIEF DESCRIPTION OF DRAWINGS

The embodiments of this invention will be described in detail, with reference to the following figures, wherein like designations denote like elements, and wherein:

FIG. 1 illustrates a lithographic system in accordance with an embodiment of the present invention.

FIG. 2 illustrates illumination and pupil filter types used in the practice of a preferred embodiment of the present invention.

FIG. 3 illustrates a common process window obtained using a conventional single exposure method of the prior art.

FIG. 4 illustrates a common process window obtained using the single mask, multiple exposure, optimized pupil filtering method of the present invention.

FIG. 5 illustrates a flow diagram depicting a method in accordance with the present invention.

FIG. 6 illustrates an alternate embodiment of the present invention that utilizes a single mask, single exposure, and two polarizations.

### DETAILED DESCRIPTION

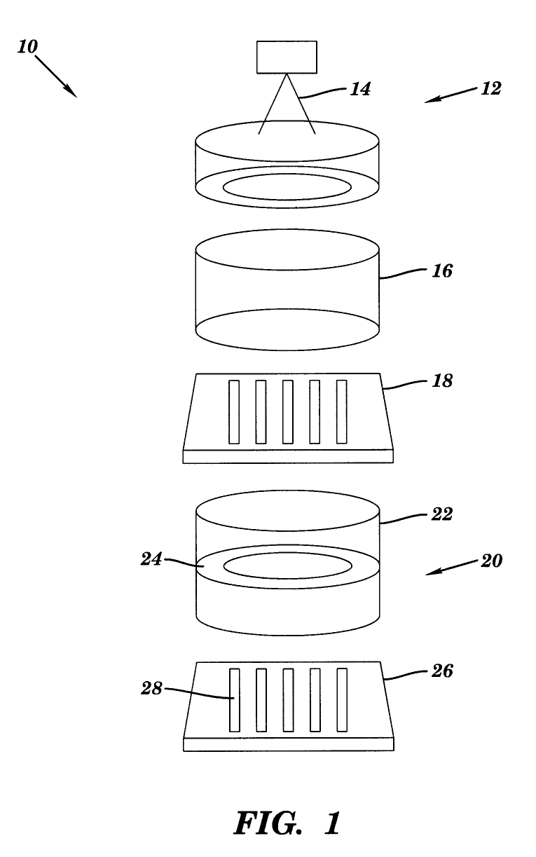

FIG. 1 schematically illustrates a lithographic system 10 in accordance with an embodiment of the present invention. The lithographic system 10 includes an illumination system 12 for providing multiple types of illumination 14. The illumination 14 is collected by a condenser lens 16 and directed to a mask or reticle 18. After passing through the mask 18, the light is collected by a projection lens system 20 comprising a projection lens 22 and a pupil filter 24, and projected to a semiconductor wafer 26 to print features 28 on the wafer 26. It is assumed for the purposes of this description that the reader has an understanding of lithographic systems commensurate with one skilled in the art. Accordingly, a detailed description of the operation of the various components of the lithographic system 10 is not presented herein.

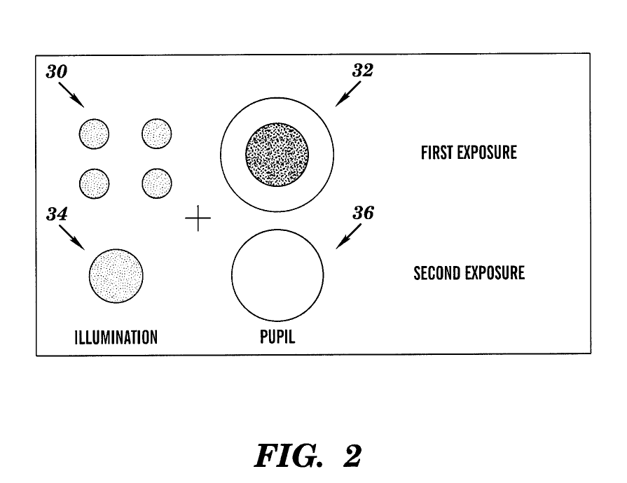

Referring now to FIG. 2, in conjunction with FIG. 1, there are illustrated the illumination and pupil filter types used in the practice of a preferred embodiment of the present invention. In this embodiment, a particular group of features on the mask 18 (e.g., contact hole patterns having different ranges of pitches) is transferred to the wafer 26 during each exposure. During each exposure, the illumination 14 and pupil filter 24 are specifically chosen in conjunction with the single mask 18 to keep diffracted orders which have a good depth of focus with regard to the group of features to be transferred to the wafer 26, and to eliminate diffractive orders which decrease depth of focus.

In the preferred embodiment of the present invention, during the first exposure, the illumination system 12 provides off-axis quadruple illumination 30 in the full lens NA, and the pupil filter 24 comprises a central obscuration filter 32. The second exposure uses disk-shaped illumination 34 with reduced NA, and no pupil filtering 36. Note that this is quite different from the prior art, since here the compact disk-shaped illumination 34 is used without a pupil filter, and a central obscuration filter 32 is employed with the quadrupole source. In a preferred embodiment of the present invention, the first exposure primarily prints high spatial frequencies in the image (small pitch patterns), and the central obscuration substantially blocks diffracted orders from patterns of larger pitch (low spatial frequency). It should be noted that it is not necessary to block very low spatial frequencies, since these are easy to print even with non-optimal illumination. Displacing the illumination off-axis increases the ability of the lens to capture orders that are diffracted at very large angles (in the direction opposite to the source displacement), thereby allowing the lens to print minimum pitch patterns. However, in a conventional lens such an off-axis arrangement is poorly suited for printing pitches of order twice the minimum pitch, and in our invention such comparatively large pitches are substantially blocked by the obscuration. Neglecting for a moment the finite size of the individual poles of the quadrupole, this blocking can be accomplished by sizing the central obscuration filter 32 to form an inscribed circle within the square defined by the poles. If the radius of the central obscuration filter 32 is denoted NAob, then when sized as an inscribed circle the obscuration will block five orders that diffract from the comparatively large pitch of magnitude wavelength/NAob. (Many of the passed orders will interfere at the doubled spatial frequency, due to spatial filtering by the central obscuration filter 32, and therefore will not contribute image modulation at the comparatively low spatial frequency given by NAob/wavelength.) Thus, the relatively long-pitch patterns that generate these low spatial frequencies are significantly attenuated in the image by the pupil obscuration. (They are restored in the second exposure.) The finite extent of the poles reduces the blocking efficiency of the central obscuration filter 32, but this can be compensated by increasing the diameter of the central obscuration filter 32.

In particular, the optimum radius NAob of central obscuration filter 32 can be calculated by:
NAob=(NAq+NAr/2)/1.414,
where NAq is the radial position of each pole of the quadrupole (the so-called pole position) and NAr the radius of each pole. Practical usable values can vary 20% or so from the calculated optimum. During the second exposure the disk-shaped illumination 34 is optimized to pass diffracted orders from the pitches whose diffracted light was substantially blocked during the first exposure, namely pitches larger than about wavelength/NAob.

The off-axis quadruple illumination 30 and disk-shaped illumination 34 can be provided using any now known or later developed illumination system(s) capable of outputting the desired illumination. (In fact, most illumination systems in today's lithography tools have this capability.) In addition, the central obscuration filter 32 can be provided using any now known or later developed technique capable of producing the desired pupil filters. Pupil filters are not widely used today, but have been recognized as an important capability for future IC lithography.

As described above, the second exposure in the preferred embodiment of the present invention does not use pupil filtering. However, in some cases, depending on the pattern(s) to be transferred to the wafer, it may be desirable to use a pupil filter during the second exposure. In addition, although the preferred embodiment of the present invention uses different types of illumination and pupil filtering during each exposure, it will be apparent to those skilled in the art that the same types of illumination and/or pupil filtering can be used in more than one of the exposures, for example with different focus settings. Further, it will be apparent to those skilled in the art that additional exposures, using the same and/or different types of illumination and pupil filters (or no pupil filter) as earlier exposures, and using the same mask as earlier exposures, can also be performed in accordance with the present invention.

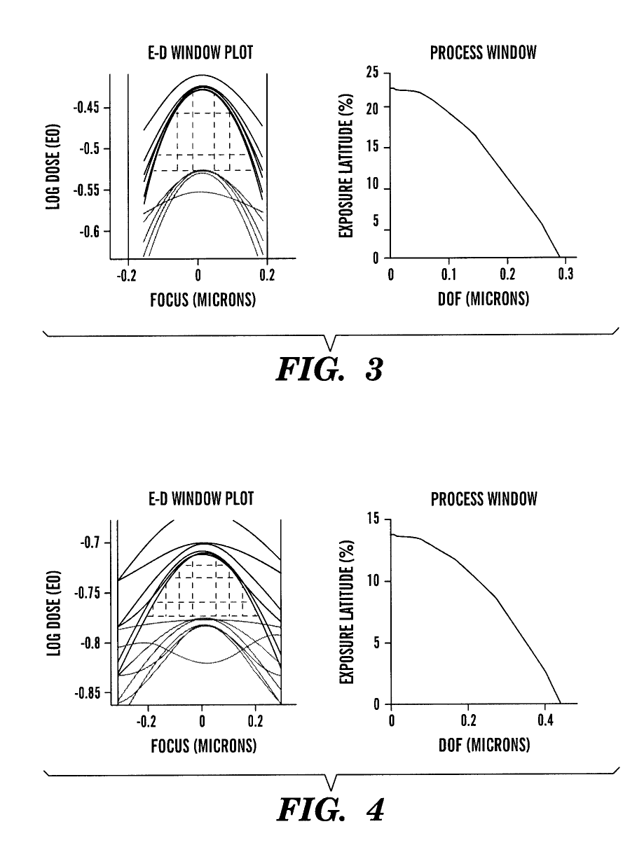

An exemplary common process window obtained using a conventional single exposure method of the prior art is illustrated in FIG. 3. This may be compared to FIG. 4, which shows an illustrative common process window achieved using the single mask, multiple exposure method (two exposures in this case) in accordance with the present invention. As is readily apparent, depth of focus (which is the most serious error sensitivity in the prior art methods) has improved significantly. The performance achieved by the single mask, multiple exposure method of the present invention is similar to that in the prior art two-mask method.

Comparing the cost of the present invention to that of other approaches, including the prior art double mask method, it has been found that the use of multiple exposures with a single mask represents only a minimal cost increment over the conventional single mask solution. Advantageously, however, it provides comparable performance to the two mask solution, which costs almost twice as much as the multiple exposure, single mask process of the present invention.

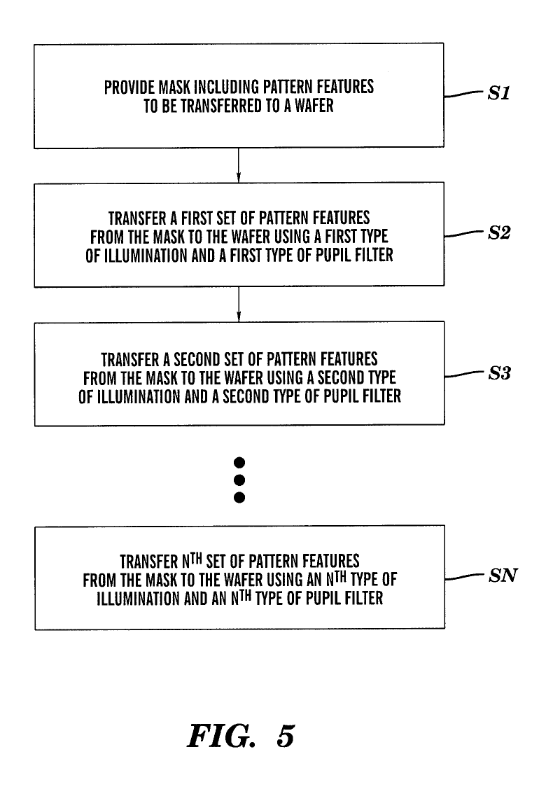

A flow diagram depicting a method in accordance with the present invention is illustrated in FIG. 5. In step S1, a mask including pattern features to be transferred to a wafer is provided. In step S2, a first set of pattern features is transferred from the mask to the wafer using a first type of illumination and a first type of pupil filter. In step S3, a second set of pattern features is transferred from the mask to the wafer using a second type of illumination and a second type of pupil filter. The second type of illumination may be the same as, or different from, the first type of illumination. Likewise, the second type of pupil filter may be the same as, or different from, the first type of pupil filter. In addition, the first and/or second type of pupil filter may comprise no pupil filter. If necessary, additional sets of pattern features may be transferred from the mask to the wafer as indicated by step SN.

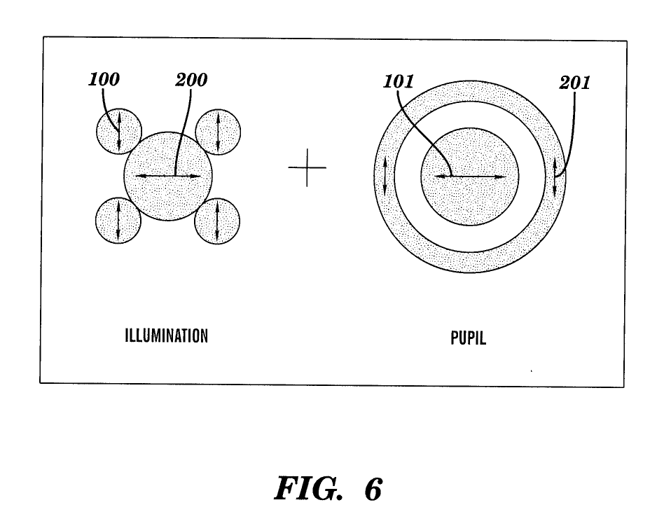

Another embodiment of the present invention is illustrated in FIG. 6. This embodiment may be adopted, for example, in tools that are dedicated to the fabrication of contact levels with an unvarying pitch range. Here one may accept the cost of complex illumination and pupil filters in order to combine the two exposures into one (while still using only one mask). This is done by encoding the two exposures and pupil conditions into separate polarization channels (for example, using wire-grid polarizers), as shown in FIG. 6. Source regions that print certain mask features with low error are assigned one polarization, e.g., vertical polarization 100. This means that illuminating rays from this first set of source regions will be polarized in approximately the same direction (100). After light from these regions diffracts from the single mask, diffracted orders which increase the likelihood of image error are blocked on the basis of polarization by regions such as 101 of the polarizing pupil filter. At the same time, source regions 200 that favorably print the remaining mask features also illuminate the wafer; these are polarized orthogonally to the first set of source regions, and may be filtered by polarizing regions 201 of the polarizing pupil filter that have an orthogonal pass direction to those for the first set of mask patterns.

While this invention has been described in conjunction with the specific embodiments outlined above, it is evident that many alternatives, modifications and variations will be apparent to those skilled in the art. Accordingly, the embodiments of the invention as set forth above are intended to be illustrative, not limiting. Various changes may be made without departing from the spirit and scope of the invention as defined in the following claims.

1. A method for printing a pattern on a wafer, comprising:
providing a mask including pattern features to be transferred to a wafer;
transferring a first set of pattern features from the mask to the wafer using a first type of illumination and a first type of pupil filter; and
transferring a second set of pattern features from the mask to the wafer using a second type of illumination and a second type of pupil filter.

2. The method of claim 1, wherein the second type of pupil filter comprises no pupil filter.

3. The method of claim 1, wherein the first type of illumination and the first type of pupil filter are chosen to reduce error sensitivity of the first set of pattern features on the wafer; and wherein the second type of illumination and the second type of pupil filter are chosen to reduce error sensitivity of the second set of pattern features on the wafer.

4. The method of claim 3, wherein the error sensitivity comprises sensitivity to defocus and sensitivity to mask error.

5. The method of claim 1, wherein the method provides an enhanced common process window for all pattern features.

6. The method of claim 1, wherein the first type of illumination comprises quadruple illumination, and wherein the first type of pupil filter comprises a central obscuration filter.

7. The method of claim 6, wherein an optimum radius NAob of the central obscuration filter is given by:
NAob=(NAq+NAr/2)/1.414,
where NAq is the radial position of the poles of the quadruple illumination and NAr is the radius of the poles of the quadruple illumination.

8. The method of claim 7, wherein the second type of illumination comprises disk-shaped illumination, and wherein the disk-shaped illumination passes diffracted orders from pitches larger than about wavelength/NAob.

9. The method of claim 1, wherein the second type of illumination comprises disk-shaped illumination, and wherein the second type of pupil filter comprises no pupil filter.

10. The method of claim 1, further comprising:
transferring at least one additional set of pattern features from the mask to the wafer.

11. The method of claim 1, wherein the pattern features comprise contact holes.

12. An apparatus for printing a pattern on a wafer, comprising:
a mask including pattern features to be transferred to a wafer;
an illumination system for providing a first type of illumination for transferring a first set of pattern features from the mask to the wafer, wherein the first type of illumination is directed through a first type of pupil filter; and
wherein the illumination system provides a second type of illumination for transferring a second set of pattern features from the mask to the wafer, through a second type of pupil filter.

13. The apparatus of claim 12, wherein the second type of pupil filter comprises no pupil filter.

14. The apparatus of claim 12, wherein the first type of illumination and the first type of pupil filter are chosen to reduce error sensitivity of the first set of pattern features on the wafer; and wherein the second type of illumination and the second type of pupil filter are chosen to reduce error sensitivity of the second set of pattern features on the wafer.

15. The apparatus of claim 14, wherein the error sensitivity comprises sensitivity to defocus and sensitivity to mask error.

16. The apparatus of claim 12, wherein the method provides an enhanced common process window for all pattern features.

17. The apparatus of claim 12, wherein the first type of illumination comprises quadruple illumination, and wherein the first type of pupil filter comprises a central obscuration filter.

18. The apparatus of claim 17, wherein an optimum radius NAob of the central obscuration filter is given by:
NAob=(NAq+NAr/2)/1.414,
where NAq is the radial position of the poles of the quadruple illumination and NAr is the radius of the poles of the quadruple illumination.

19. The apparatus of claim 18, wherein the second type of illumination comprises disk-shaped illumination, and wherein the disk-shaped illumination passes diffracted orders from pitches larger than about wavelength NAob.

20. The apparatus of claim 12, wherein the second type of illumination comprises disk-shaped illumination.

21. The apparatus of claim 12, wherein the pattern features comprise contact holes.

22. A method for printing a pattern on a wafer, comprising:
providing a mask including pattern features to be transferred to a wafer; and
transferring a plurality of sets of pattern features from the mask to the wafer using a single exposure and multiple polarization channels.

23. The method of claim 22, wherein each polarization channel corresponds to a different exposure and pupil condition.
